(19) United States
(12) Patent Application Publication
(10) Pub. No.: US 2025/0046488 A1
(43) Pub. Date: Feb. 6, 2025

(54) CONIC ZONEPLATE FABRICATION TECHNIQUE

(71) Applicant: UCHICAGO ARGONNE, LLC, Chicago, IL (US)

(72) Inventors: Raymond P. Conley, Glen Ellyn, IL (US); Lahsen Assoufid, Chicago, IL (US); Michael J. Wojcik, Orland Park, IL (US); Matthew J. Vescovi, Mattituk, NY (US)

(73) Assignee: UCHICAGO ARGONNE, LLC, Chicago, IL (US)

(21) Appl. No.: 18/792,116

(22) Filed: Aug. 1, 2024

Related U.S. Application Data
(60) Provisional application No. 63/530,428, filed on Aug. 2, 2023.

(51) Int. Cl. G21K 1/06; C23C 14/04

(52) U.S. Cl. CPC G21K 1/067; C23C 14/042

(57) ABSTRACT

The invention provides a method for fabricating x-ray focusing optics, the method comprising supplying a first cathode forming a first channel, inserting a substrate within the channel; and charging the first cathode to sputter first cathode material to a surface defining the substrate, thereby forming a first zone film onto the surface. Also provided is a monolithic X-ray diffraction lens having sub 10 nanometer resolutions, the lens comprising a substrate overlaid with discrete regions of metal, the regions integrally molded with the substrate.

### PRIORITY

This Utility patent application claims the benefit of U.S. Provisional Application No. 63/530,428, filed on Aug. 2, 2023, the entirety of which is incorporated herein by reference.

### CONTRACTUAL ORIGIN OF THE INVENTION

This invention was made with government support under Contract No. DE-AC02-06CH11357 awarded by the United States Department of Energy to UChicago Argonne, LLC, operator of Argonne National Laboratory. The government has certain rights in the invention.

### BACKGROUND OF THE INVENTION

### 1. Field of the Invention

This invention relates to x-ray diffraction substrates and more specifically this invention relates to a substrate and a method to produce a substrate for diffracting x-rays having resolutions below 10 nanometers (nm).

### 2. Background of the Invention

There is an ever increasing need for higher resolution and performance, related to the focusing of x-rays for use in elucidating atomic structures. Multiple beam lines are pushing for 10 nm and small focal spot size. The highest resolution goal is from the Ptychography+Nanoprobe beamline at the Advanced Photon Source (APS) at Argonne National Laboratory, Argonne, IL (hereinafter Ptychoprobe) at 5 nm. The goal of the Ptychoprobe is to realize the highest possible spatial resolution X-ray microscopy both for structural and chemical information. However, current resolutions barely approach 10 nm.

Increased resolution produces a direct improvement on sample detail, while efficiency gains will improve speed and throughput compared to the current generation of nano-focusing optics available. Nano-focusing hard X-ray optics, designed for greater than 8 kiloelectron volt X-ray energy, are needed for the Ptychoprobe and other Advanced Photon Source-Upgrade beamlines at research institutions. Also, current beamlines could greatly benefit from improved optical technology.

Zone plates are a commonly used x-ray focusing optic for nanometer spot sizes (between 50 nm and 500 nm). A zone plate is a device used to focus radiation (such as light) which exhibits wave character. Unlike lenses or curved mirrors, zone plates use diffraction instead of refraction or reflection. Based on analysis by French physicist Augustin-Jean Fresnel, they are sometimes called Fresnel zone plates in his honor.

Zone plates comprise an alternating set of transparent and opaque rings that diffract light to constructively interfere (i.e., focus) at a single point. They are considered more useful and economical for focusing and imaging at non-visible (IR, UV, XRAY, etc.) spectrums of light compared to reflective or refractive materials in certain situations. The diffractive optics of zone plates provide radially varied grating spacing. Ideally, the zones are positioned within one-third the width over their diameter. In other words, each zone should be positioned with respect to the ideal zone radius to within one-third of its width; this to minimize optical aberrations.

X-ray Zone Plates tend to be on the order of tens to hundreds of microns in diameter and are generally produced either through Lithography and or Etching of the desired materials, or deposition of alternating zones onto a substrate. The zones must be thick enough along the beam direction to cause sufficient phase shift for efficient focusing, particularly for X-rays with energy greater than 5 kilo-electron volts.

When focusing X-rays with zone plates, increasing resolution and focusing efficiency requires increasing the aspect ratio; i.e., the zone thickness over the outermost zone width, of the plate. But, it is in efforts to maximize aspect ratios that problems begin to arise. (For example, an ideal aspect ratio for 10 keV X-rays for 20 nm spot size focusing is greater than 100 in a zone plate made with gold zones.) These problems include the collapse of zone structure due to collateral forces which occur during fabrication processes. Lithography-based processes often cannot achieve desired aspect ratios, particularly for sub-100 nm focal spot sizes and greater than 10 keV X-ray energy focusing.

High aspect ratio zone plates can be affected by zone collapse due to capillary forces imposed by process fluids during fabrication; as such, capillary collapse destroys sought-after straight walls of zones. Such zone plates are compromised with respect to optical performance. This is a drawback of top down zone plate fabrication such as lithography.

Bottom-up fabrication is also used to fabricate hard X-ray zone plates. This method deposits alternating material to act as the zones onto a round substrate. Bottom-up techniques can achieve much smaller zone widths and aspect ratios compared with lithography-based methods, but with the disadvantages of limited diameter (due to long deposition times, insufficient deposited zone quality, and insufficient control of layer deposition rates.

Variations of the deposition type of optics have been attempted but the basic underlying problems have not all been adequately addressed due to the type of deposition methods and substrates previously used. For example, flat cathodes depositing on round substrates have limited deposition rates, due to the need for rotating the substrate to assure complete coating. This limits the zone plate diameter and causes defect propagation due to shadowing, that latter of which occurs while rotating the sample in front of the flat cathode.

Another method for depositing zones includes atomic layer deposition, which is a form of chemical vapor deposition. High quality thin films, conformally coating a round substrate is possible. However, the materials available are limited. Also, standard atomic layer deposition is extremely slow, orders of magnitude slower than cathode sputtering.

Multilayer Laue Lenses (MLL) are often prepared by depositing thousands of nanometer-thick layers onto a smooth substrate, alternating between a material of high atomic number and one of low atomic number. MLLs are fabricated using planar substrates, since they can be obtained with the atomically-smooth surface needed to achieve a high-quality multilayer structure. MLLs are similar to zone plates and have the capability of generating small focal spot sizes with X-rays. However, MMLs require two optics for 2-D focusing, which complicates application since a pair of optics are required to be aligned at the accuracy of the desired focal spot size.

As depicted in FIG. 1A, MLLs have primarily been fabricated as half aperture, non-symmetrical optics similar to a pair of half lenses, with the numerical aperture as a function of twice the smallest layer thickness. An optic's aperture is the area of the optic which collects X-rays for focusing. Since MLL's are deposited on one side of a substrate, twice the multilayer thickness would need to be deposited to equal the aperture of a zone plate discussed in this invention which has zones deposited around a circular substrate. Numerical aperture is the focusing power of the lens, and is equal to half the aperture divided by the focal length. (“Numerical aperture” is a half collecting angle value versus “divergence” which is the full collecting angle. Zone plates still have twice the aperture size compared with MLL's and therefore twice the NA.) Since the zone plates in this patent have twice the aperture of an MLL for an equivalent focal length, the numerical aperture will be twice as large.)

FIG. 1B shows a full aperture optic which is the result of fabricating MLL multilayers on both sides of a flat substrate in a single MLL lens. FIG. 1B can also be construed as representative of a zone plate generated by the invention. The arrows in FIGS. 1A and 1B show the passage of radiation through the layered substrate.

A need exists in the art for a focusing media plate and a method to produce zone plate focusing media to attain sub-10 nm resolutions. The invented optic would meet core needs for ≤5 nm hard x-ray focusing as well as potentially replace lithographically-produced zone plates. The optics generated by the invented method should be radially symmetrical, comprise a single substrate, and cover the whole aperture, this to better match the numerical aperture, based on the smallest zone or layer thickness.

### SUMMARY OF INVENTION

An object of the invention is to provide a high resolution x-ray focusing lens and a method for making the lens that overcomes many drawbacks of the prior art.

Another object of the invention is to provide an x-ray diffraction optical material and a method for producing the optical material. A feature of the invention is obtaining resolution values below 10 nm, and preferably between 3 and 6 nm. An advantage of the invention is the provision of sharper images of samples subjected to x-ray diffraction analysis.

Still another object of the invention is to provide a material for focusing x-rays. A feature of the material is radially symmetric layering around the equator of the material. An advantage of this symmetric layering is that it enables the resulting construct to generate a symmetrical focal spot during diffraction activities.

Yet another object of the invention is to provide a method for preparing focusing substrates for use in X-ray diffraction. A feature of the invention is surrounding a focusing substrate with a cylindrical cathode or plurality of cathodes. This process may be done at ambient temperature (for example room temperature) and at low pressure (e.g., 2-4 millitorr). An advantage of the invention is the production of conformal, continual sputter layers, serially applied in instances where a plurality of cathodes are used. Another advantage is the elimination of shadowing, which occurs when using a flat cathode. (The aforementioned shadowing is akin to the dark areas behind an object illuminated with a point light source. It causes defects in the continual layers during rotation of the sample in an effort to coat all parts.)

Another object of the present invention is to provide a lens capable of generating high resolution images using radiation as the focusing media. A feature of the invention is the incorporation of nanometer sized zones below 5 nm to focus x-rays. An advantage of the invention is the production of an intense x-ray beam at the focus.

Briefly, the invention provides a method for fabricating x-ray focusing optics, the method comprising supplying a first cathode forming a first channel, inserting a substrate within the channel; and charging the first cathode to sputter first cathode material to a surface defining the substrate, thereby forming a first zone film onto the surface. These steps are repeated until the desired layers and layer numbers are generated.

Also provided is a substrate for focusing x-rays, the substrate comprising a conical substrate, a tapered cylinder, or a sphere. Preferably, the optical substrate has radially symmetric layering extending from its equator.

The invention further provides an X-ray diffraction lens having sub 10 nanometer resolutions, the lens comprising a substrate overlaid with discrete regions of alternating transparent and absorbing materials. The regions are integrally molded with the substrate, wherein the substrate is typically a high-Z material to absorb non-diffracted radiation. The x-ray low-Z transparent materials are selected from the group consisting of sapphire, quartz, silicon, and aluminum silicide (AlSi). The high Z absorbing material is selected from the group consisting of tungsten silicide, molybdenum silicide, and combinations thereof.

### BRIEF DESCRIPTION OF DRAWING

The invention together with the above and other objects and advantages will be best understood from the following detailed description of the preferred embodiment of the invention shown in the accompanying drawings, wherein:

FIG. 1A is a view of a half aperture layered substrate;

FIG. 1B is a view of a full aperture layered substrate;

FIG. 2 is a cross section scanning electron micrograph (SEM) image of deposited material on a zone plate, in accordance with features of the present invention;

FIG. 3 is a cross section SEM plan view of a representative lithography fabricated zone plate;

FIG. 4 is an isometric view of a cross section of a zone plate having a spherical core substrate, in accordance with features of the present invention;

FIG. 5 is a schematic depiction of a focusing substrate prior to insertion and treatment within and by a cathode, in accordance with features of the present invention;

FIG. 6A is an elevational view of a conic shaped substrate, in accordance with features of the present invention;

FIG. 6B is an elevational view of a conic shaped substrate overlaid with material after sputtering operations, in accordance with features of the present invention;

FIG. 6C is an elevational view of the sputtered conic substrate shown in FIG. 6B with score lines and a mount pin holder attached, in accordance with features of the present invention;

FIG. 6D is an elevational view of the final construct after cutting along the score lines depicted in FIG. 6C, in accordance with features of the present invention;

FIG. 6E is schematic view of x-rays focused by the diffraction substrate generated by the invented method, in accordance with features of the present invention;

FIG. 7 is an elevational view of a deposition chamber based on a pair of cylindrical cathodes, in accordance with features of the present invention: and

FIG. 8 is a schematic view of an optics shaping procedure, in accordance with features of the present invention.

### DETAILED DESCRIPTION OF THE INVENTION

The foregoing summary, as well as the following detailed description of certain embodiments of the present invention, will be better understood when read in conjunction with the appended drawings.

All numeric values are herein assumed to be modified by the term “about”, whether or not explicitly indicated. The term “about” generally refers to a range of numbers that one of skill in the art would consider equivalent to the recited value (e.g., having the same function or result). In many instances, the terms “about” may include numbers that are rounded to the nearest significant figure.

The recitation of numerical ranges by endpoints includes all numbers within that range (e.g. 1 to 5 includes 1, 1.5, 2, 2.75, 3, 3.80, 4, and 5).

The following detailed description should be read with reference to the drawings in which similar elements in different drawings are numbered the same. The drawings, which are not necessarily to scale, depict illustrative embodiments and are not intended to limit the scope of the invention.

As used herein, an element or step recited in the singular and preceded with the word “a” or “an” should be understood as not excluding plural said elements or steps, unless such exclusion is explicitly stated. As used in this specification and the appended claims, the term “or” is generally employed in its sense including “and/or” unless the content clearly dictates otherwise.

Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

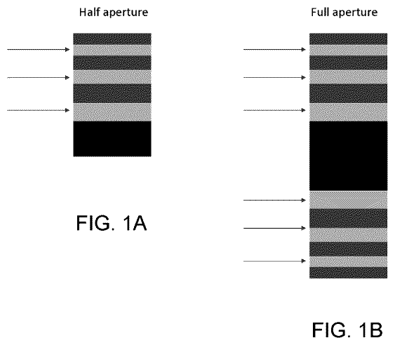

An embodiment of the invention provides the fabrication of X-ray focusing optics using a conical substrate covered in a plurality of layers deposited via a cylindrical deposition cathode system. Compared with MLL, the optics generated by the invented method are radially symmetrical, full aperture optics similar to a standard zone plate. As discussed above in reference to FIGS. 1A and 1B, full aperture optics will have twice as large a numerical aperture compared with half aperture optics. The effective result is that the optics fabricated with the invention has twice as small a focal spot size as an equivalent half-aperture MLLs (for example 5 nm versus 10 nm), and therefore double the resolution, and none of the co-dependent optical alignment constraints as the equivalent MLLs.

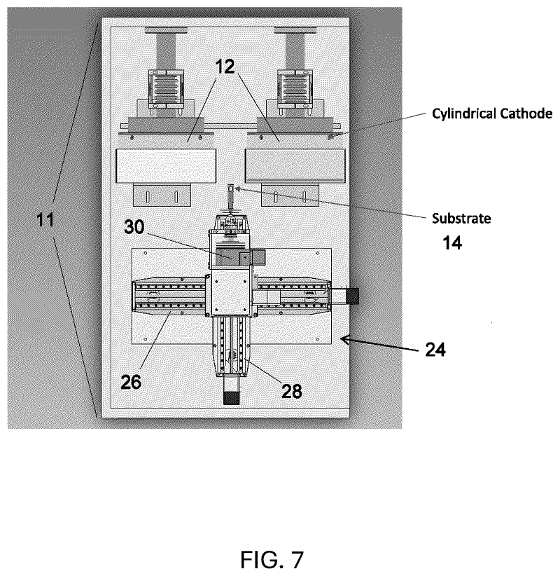

The deposition system uses a cylindrical cathode or a plurality of the cylindrical cathodes (e.g., a pair, as depicted in FIG. 7) to coat a round substrate by more closely matching the shape (compared with a flat cathode) to create a conformal coating, and a multi-layer coating. This is done by inserting the substrate into the center of a first cathode, allowing sputtering to occur, then repeating the process with a second cathode, third cathode, etc., and repeating the sputter process in each cathode, depending on how many different layers are desired. For example, if 4 layers are desired, then 4 sputter processes will be involved in total. For a process involving w different materials, 2 sputter processes of each material in alternating materials (up to 4 total layers) would take place. In summary of this point, the number of sputtering deposition events will determine the number of layers created.

Standard coating times per layer range from 10 sec to 150 sec, longer and shorter in certain cases. The deposition rates used for zone plate optics range from about 0.1 nanometers per second to 0.6 nanometers per second depending on applied power to the cylindrical cathode and material deposited. The coating is applied to be consistent in its thickness throughout and therefore contains no breaks, or blemishes. This consistency is rendered via choice and purity of cathode material and the magnet strength, its application and duration thereof, factors of which are determined empirically. The sample is also rotated while undergoing the sputter process all of which will even out any differences in deposition in the cylindrical cathode. The result are layers without inter-diffusion or interlayer roughness propagation so as to be optimized as an X-ray optic.

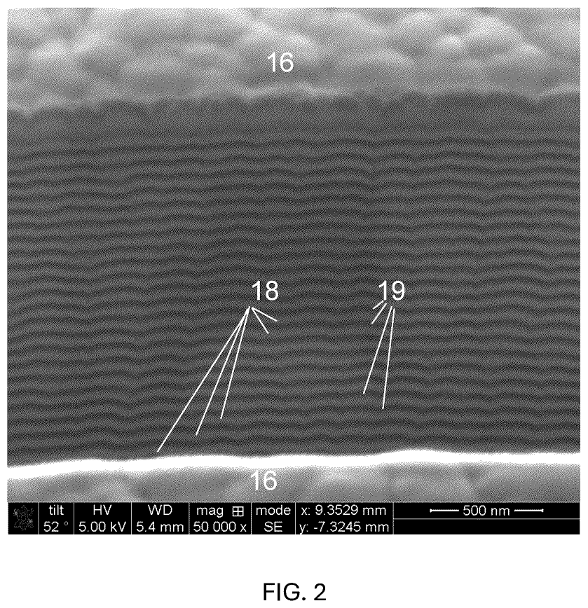

The invention provides methods for additive (i.e., bottom-up) zone plate fabrication, as opposed to the prior art's lithographically based methods which are not as capable in the sub-10 nm feature size regime. FIG. 2 depicts a portion of a zone plate 16 with discrete layers overlaying its surface. Generally, higher Z materials are more radio-opaque that lower Z materials. For example, in the figure, the lighter-colored layers 18 comprise radio-opaque high Z materials (e.g., tungsten silicide) and the darker layers 19 comprise relatively low Z materials such as radio-transparent aluminum silicide (AlSi). In this particular embodiment, the darker layers 19 comprise a lower Z material compared to the lighter layers, which comprise a high Z material. (In SEM images, the contrast is reversed: there is more signal from the tungsten silicide material (high Z material) than the aluminum silicide. This is most likely due to the higher conductivity of the high Z material.)

The lighter layers are exposed through a cross sectioning method with a focused ion beam (FIB) tool. The invented conic zone plate deposition system uses sputtering to achieve this bottom-up type layering, akin to additive manufacturing (e.g., 3-D printing). Resolution is determined by the smallest (thinnest) layer thickness deposited.

FIG. 2 image was taken with the sample tilted at 52 degrees relative to the viewer. The scale bar is 500 nm. The electron energy was 5 keV.

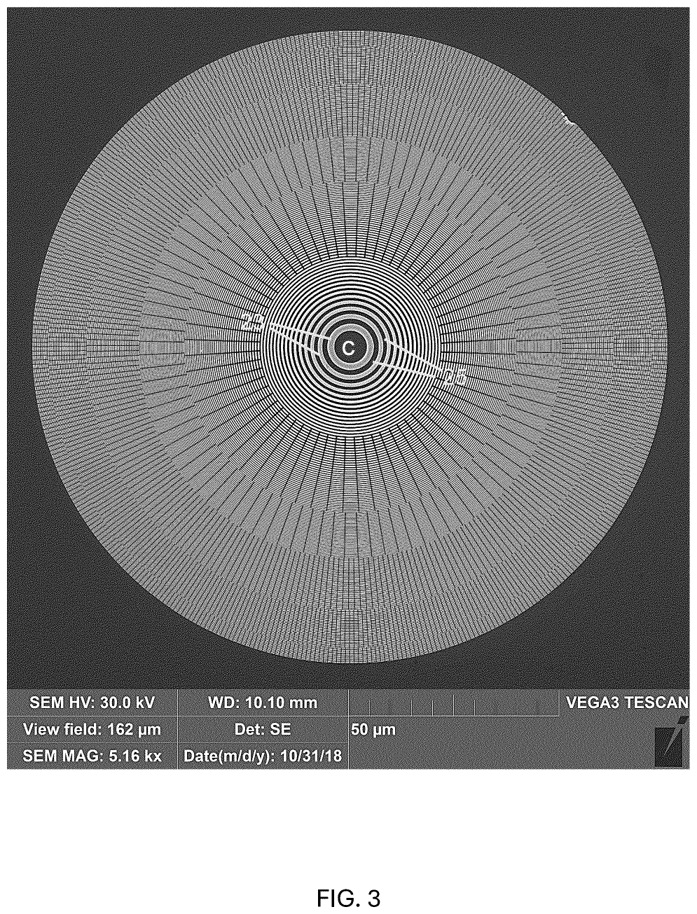

FIG. 3 is an SEM image of a lithographically fabricated zone plate with gold as the radio-opaque material. The center “C” of FIG. 3 is the original substrate material overlaid with alternating layers of deposited radio-opaque material 23 and radio-transparent material 25. In FIG. 3, the high-Z material for radio-opaque is visually brighter than the transparent material. The opaque material is gold while the transparent is primarily silicon nitride.

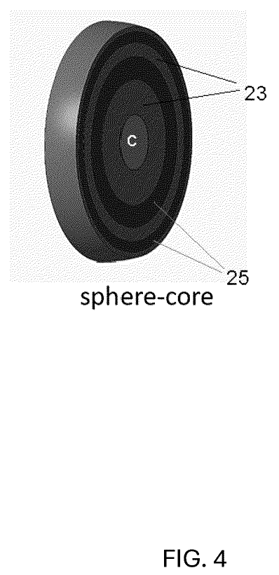

FIG. 4 is an isometric view of an equatorial slice of a spherical substrate overlaid with radially applied, alternating layers of radio-transparent and radio-opaque material. This view is reminiscent of tree rings seen on a cross section of a tree trunk. The center region “C” of FIG. 4 is the original substrate material. Alternating layers of deposited radio-transparent material 23 and deposited radio-opaque material 25 are also shown, those layers disposed radially from the center region C.

FIG. 4 depicts a radio-transparent ring immediately adjacent to the center region C, whilst a radio-opaque ring is shown circumscribing the transparent ring. The reverse paradigm is also enabling, wherein a radio-opaque layer contacts the center region C and a radio-transparent layer contacts the radio-opaque layer. Preferably, the radius spacing in each ring follows the known zone plate equation.

### Deposition Protocol

Bottom-up fabrication of diffractive focusing optics has several requirements on the substrate and deposition to achieve a suitable optic. The invention requires shape (sphericity) control and smoothness of the round substrate upon which the zones are deposited. The invention provides the ability to build zones without inter-diffusion or interlayer roughness propagation. The invented method also provides the precision upon which zone placement can be controlled in a new three-dimensional deposition geometry.

Software used to facilitate the deposition process is a combination of EPICS control and Python software created using Bluesky experimental control and data collection libraries. These libraries have been used in other deposition systems such as Argonne Laboratory's Modular Deposition System (MDS) given its flexibility to utilize many deposition sources and Conic Zone Plate Deposition System (CZP). EPICS control framework is found at https://epics-controls.org/. Bluesky data collection frame-work can be found at https://github.com/bluesky or https://nsls-ii.github.io/bluesky/. (Both are freely available)

Generally, this additive-type manufacturing embodies depositing high and low Z materials on the substrate (either flat or round), then sectioned to design the preferred optic's size.

After deposition, the deposited optical substrate is removed from the deposition system and mounted into various systems to slice out the usable optic. This final optics shaping may be optimized via modern FIB tool techniques. FIB uses a high energy beam of focused ions to mill materials. It is instrumental in controlling the final shape of substrates having sub-100 nm thicknesses. Other shaping techniques include laser ablation and chemical mechanical polishing, which could be used for quicker sectioning.

Deposition processes for zone fabrication requires control of the deposited layer thickness of less than 1 nanometer. Roughness of the deposited film is required to have rms value of less than one-third (⅓) of the smallest layer thickness. Preferred total deposited thickness is more than 10 microns to be useful as focusing optics, since deposited thickness is related to the collecting aperture of the optic. The thickness of the deposited regions are typically three times the width of the regions. The sectioned optic's final thickness is determined by the x-ray energy and which materials were used to obtain optimum phase contrast. In a preferred embodiment of the invention, the thickness of the deposited regions result in twice the thickness of total aperture since all sides of the substrate would be coated. A 10 micron thick deposition will account for a 20 micron aperture.

The finished diffractive optic may be mounted onto a secondary holder which may be readily mounted to synchrotron beamlines for use with X-rays.

### Cathode Shaping Detail

In an embodiment, the invention comprises a fabrication method using cylindrically shaped sputtering cathodes to deposit multilayers onto curved substrates (e.g., round substrates such as spheres, wires, cylinders) and uncurved substrates (e.g., flat surfaces such as planes, squares, rectangles, parallelograms). The deposition utilizes film thickness as a function of radius. Deposition rates from the cathodes at different applied powers are known and via the process described below, the rates are used with the Bluesky libraries to control the deposition process. Each layer thickness is calculated from zone plate equations which is converted into a deposition time. The curved and uncurved substrates are inserted into each cathode and power applied for the calculated time with the sample passed between two or more cathodes until the final multilayer structure is completed.

One such substrate subjected to sputtering is a zone plate. As such, the resulting optic substrate is a zone plate upon which material is deposited.

Variations to properties of the created optic include duty cycle optimization. (In the art, this is known as “Gamma” or the ratio of the thickness of one of the layers vs. the total bilayer thickness.) Test substrates are used to deposit layers of material from the cathodes over a set period of time. After deposition, the test substrates are taken to a tool to expose the deposited layers, usually a FIB, and the exposed layers are examined to determine the thickness of material deposited over the set period of time. The resulting deposition rate is then used to calculate the desired duty cycle, or comparison of layer thickness deposited; usually 1:1 duty cycle of equal layer thickness per bilayer.

The invention provides a myriad of ways to generate diffracting zone plates. However, the invented technique can be applied to other samples and optics, for example, X-ray beam expanders (similar concept to the zone plate but with different layer thicknesses) and volume test samples for tomographic reconstruction.

Sputtering from cylindrical cathodes is discussed below, wherein the target substrate is positioned within the cylinder for a symmetrical overlayment of diffracting material. Other methods include deploying magnetic fields axisymmetric to the optical axis and directly behind the substrate in order to confine and direct plasma bombardment; this to enhance film performance. Compared with a flat cathode which can only deposit on one side of a round substrate, the deposition on all sides of the cylinder substrate provides faster deposition, reduced deposition defects from small point defects in the substrate, conformal coating on the cylinder, as well as other minor enhancements.

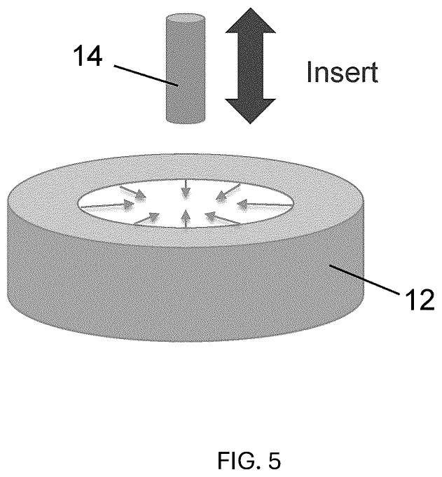

FIG. 5 is a schematic diagram of the method for producing an X-ray diffracting zone plate, the method generally designated as numeral 10. A cylindrical first cathode 12 is provided. Exemplary cathodes are commercially available and be comprised of electrically conductive material selected from the group consisting of steel, aluminum, copper and rare earth magnets, their alloys and combinations thereof.

The cathode 12 is adapted to receive a substrate 14 which ultimately comprises the diffraction lens. The cathode is emerged, then the substrate 14 is nested within the cathode, and sputtering commences. Once a layer is established on the substrate 14, the first cathode is removed and a second cathode is utilized to generate a second layer (I.e., the next layer) on the substrate 14. The substrate is then moved to the first cathode (or perhaps a third different cathode) and the deposition steps are repeated until the requisite number of alternating layers of high and low Z materials is reached.

After a series of sputtering operations occurs, the substrate is removed and sliced into discs having desired thicknesses (e.g., a few microns to tens of microns). Alternatively, the substrate is milled into a cone or another shape. A cone or spherical substrate shape approximates an ideal zone plate focusing optic for nanometer size focusing. The conical shape aids in focusing below 10 nm and approaching 5 nm spot size. A conical shape is an approximation of the curved and tapered zones discussed supra. Choice of substrate shape is determined via available material and techniques for shaping the substrate. As discussed supra, FIB and/or other nanofabrication or etching-based techniques may be utilized for ultimate shaping of the substrate core.

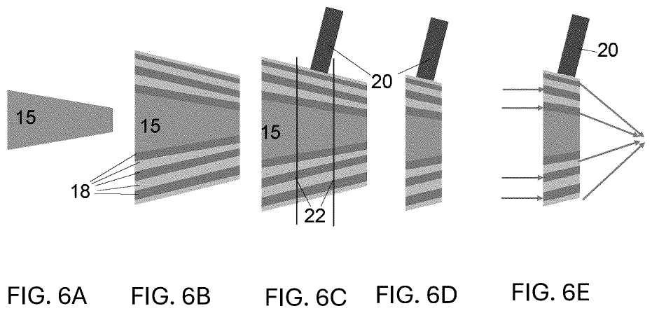

FIGS. 6A-D show a conic shaped substrate 15 in various stages of fabrication. The substrate 15 is shown in FIG. 6A before sputtering. This raw substrate may comprise any x-ray transparent material, including, but not limited to tungsten, sapphire, quartz, silicon, and aluminum oxide.

FIG. 6B shows the substrate having six discrete layers 18 of two different materials, in serial fashion on its surface. The layers are shown conformal and continuous such as no breaches exist between the layers. This multilayer deposition is generated using two cathodes. The layers may comprise high Z and low Z materials. As such, the high Z materials may be selected from the group consisting of high Z material selected from the group consisting of aluminum silicide, tungsten silicide, molybdenum disilicide, silicon and combinations thereof.

FIG. 6C shows the overlaid substrate 15 with a mount pin holder 20 attached thereto. Also designated are lines delineating a cut out section 22. FIG. 6D shows the optic after the construct is subjected to final milling, shaping or cutting. FIG. 6E shows the final construct, after milling, subjected to x-rays. Substrate geometries considered are both the cylindrical geometry milled into a conic section and a spherical geometry for a spherical core section. It is evident from this figure how the conic structure aids in focusing the beams to a specific focal point. The un-diffracted x-rays are shown entering the lens from the left at generally a right angle to the upstream surface of the construct. The diffracted x-rays are shown exiting the downstream end of the substrate on the right at an angle to the downstream surface of the structure. The diffracted x-rays converge to a predetermined focal point, which may be defined by a detector, film, or other analyzer means.

### Multiple Cathode Staging Detail

The invention provides mechanics of the rotation stage and cylindrical source. Generally, a plurality of sputtering sources is utilized. FIG. 7 is a plan view of a double cathode configuration. Two cylindrical cathodes 12 are shown positioned side by side within a deposition chamber housing 11 such that their longitudinal axes are parallel with each other. A substrate 14 is positioned on a positioning system 24 comprising a first cathode alignment track 26 adapted to align the substrate with each of the access channels of the cylindrical cathodes in a serial fashion. A second track 28 moves the substrate in a longitudinal axis relationship with each of the cathode access channels. As such, the first track 26 moves the substrate 14 from alignment with one cathode, to alignment with another. Once so aligned, the first track moves the substrate into the cathode with which it is currently aligned. The substrate is rotated around the axis parallel to the second track via a rotation stage 30 with the purpose to smooth any variation in the cylindrical cathode.

The housing may be constructed to maintain a controlled atmosphere such as containing an inert gas (e.g., nitrogen, argon) controlled atmosphere such as containing an inert gas (e.g., nitrogen, argon) and about 1×10⁻⁵ (1×10⁻³ Pa) pressure to optimize the deposition process. The housing 11 may also be constructed to maintain a predetermined temperature ranging from 0 C to 75 C, and/or pressures ranging from 2×10⁻⁸ psi to 15 psi.

The invention enables the generation of substrates having very high resolutions. To obtain below 5 nm focusing resolution, zones are required to be tapered, or ideally, curved which are implemented via the substrate and deposition process. Tapering zones can be done by controlling the insertion of the conical substrate into the cylindrical cathode. If the larger diameter end of the conical substrate is facing towards the cathode, the deposition thickness per zone is increased through being in the deposition field for slightly longer than the end of the substrate further away from the cathode. This can be further controlled by the velocity of the substrate inserted and removed from the channel formed in the cathode.

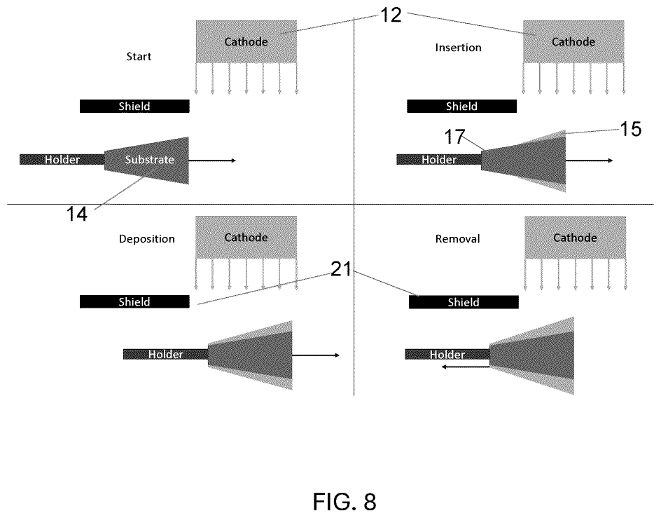

As depicted in FIG. 8, curved zones are achieved via the use of a rounded, conical, or spherical substrate 14 in combination with tapering the zones. For drawing simplification, only one part of the cylindrical cathode is shown. As discussed supra, deposition occurs to all sides of the substrate simultaneously. Shadowing can also be used (e.g., where there is a shield 21, in this case perhaps a cone/shallow funnel shape) to produce a steeper gradient. (The shield may comprise any material to interrupt passage of sputtered material from the cathode to the substrate so as to prevent deposition from occurring.) In this instance, a metal shield 21 would be positioned between the substrate 14 and the cathode 12. The shield may move in a direction parallel to the longitudinal axis of the substrate and the longitudinal axis of the cathode. (The shield motion may be in unison with the substrate.) Alternatively, the shield may move in a direction not parallel to the longitudinal axis of the substrate (e.g., parallel to the latitudinal axis of the substrate. The substrate and cathode may move relative to the shield. Alternatively, the shield may be designed to be aligned closer or further away from the substrate. Additionally, the shield with the ability to move parallel to the longitudinal axis of the substrate can be used to reduce any tapering on zone deposition through movement after the substrate is moved into the cathode and cathode energized.

That part of substrate (i.e., the distal end 15) which sees cathode plasma first will have a thicker layer deposited its proximal end 17. The amount ultimately deposited can be controlled with velocity of insertion of the substrate and/or the shield into the channel. And the distance between the shield and the substrate. This facilitates the generation of finely tuned sub-10 nm zones, (e.g., ˜4-9 nm zones) with a zone shape to better approximate ideal zone profiles. This aspect of the invention generates variations in thicknesses of the overlaying layers onto the substrate, such that proximal surfaces of the substrate are overlaid with thinner layers compared to distal surfaces of the substrate. This tapering of thickness enables each zone or layer within the lens to lie at the proper angle for the locally-optimum tilt.

Ellipsoidal zones require no layered tapering, making these shapes preferable. These invented techniques improve upon existing geometries and enable diffraction optics with both curved zones and arbitrarily-high aspect ratios.

In summary, the invention provides a method for deposition which exposes the entire radius of a substrate to similar deposition conditions through

The use of inverted cylindrical cathodes. The invention utilizes round (conic, or spherical) substrates to produce zone plates neither anticipated nor suggested by flat polishing or wire-based paradigms.

### Example 1

A pair of cylindrical sputtering sources analogous to that depicted in FIG. 7 was purchased (Angstrom Sciences, Duquesne PA) and incorporated into the invented deposition system.

Cylinders with a conical-like shape (conic substrate) were acquired from Alcorix Co. (Plainfield, IL) with 30 microns major diameter which were on a silicon wafer with hundreds of similar cylinders. The samples were diced in a high-speed dicing saw, designed for cutting silicon wafers, to an individual sample size of 200×200×500 micron rectangular volume. These samples with the conic substrate were mounted to a stainless steel pin using epoxy adhesive with the conic substrate facing away from the pin.

The pin was mounted in the cylindrical cathode deposition system with the designed pin holders. A 10-30 nanometer thick layer of chrome was deposited by rotating the cylinder with respect to the flat cathode with chrome target material. The small defects and roughness of the chrome deposition is counter balanced by the adhesion properties of depositing the next materials to the chrome. The multilayer was then deposited onto the substrate by moving back and forth between the two cathodes and depositing each material onto the substrate. Material one was AlSi and material two is tungsten silicide. The deposition rates were measured and used to determine deposition time for each layer, and deposition layer thickness was calculated to match the zone plate zone profile.

Deposition rates for these examples varied and ranged from between 0.15 to 1 nanometers per second with applied power between 50 and 250 watts. For example, deposition rates for 75 watts of applied power to the cathodes was approximately 0.18 nanometer per second for AlSi material. Total deposition time for tens of micron layer is in the order of tens of hours. Another exemplary deposition protocol is 75 watts of applied power onto a tungsten silicide, with sputtering material having a 0.28 nanometer per second deposition rate. The power supply read supplied 344 volts and 0.218 A of current to the cathode for the 75 watts of applied power.

It is understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to define the parameters of the invention, they are by no means limiting, but are instead exemplary embodiments. Many other embodiments will be apparent to those skilled in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the terms “comprising” and “wherein.” Moreover, in the following claims, the terms “first,” “second,” and “third,” are used merely as labels, and are not intended to impose numerical requirements on their objects. Further, the limitations of the following claims are not written in means-plus-function format and are not intended to be interpreted based on 35 U.S.C. § 112, sixth paragraph, unless and until such claim limitations expressly use the phrase “means for” followed by a statement of function void of further structure.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” “more than” and the like include the number recited and refer to ranges which can be subsequently broken down into subranges as discussed above. In the same manner, all ratios disclosed herein also include all sub ratios falling within the broader ratio.

One skilled in the art will also readily recognize that where members are grouped together in a common manner, such as in a Markush group, the present invention encompasses not only the entire group listed as a whole, but each member of the group individually and all possible subgroups of the main group. Accordingly, for all purposes, the present invention encompasses not only the main group, but also the main group absent one or more of the group members. The present invention also envisages the explicit exclusion of one or more of any of the group members in the claimed invention.

The embodiment of the invention in which an exclusive property or privilege is claimed is defined as follows:

1. A method for fabricating x-ray focusing optics, the method comprising
a) supplying a first cathode forming a first channel,
b) inserting a substrate within the channel; and
c) charging the first cathode to sputter first cathode material to a surface defining the substrate, thereby forming a first zone film onto the surface.

2. The method as recited in claim 1 further comprising inserting the surface overlaid with the first zone film in a channel of a second cathode and charging the second cathode to sputter second cathode material onto the first zone film to form a second zone film overlaying the first zone film.

3. The method as recited in claim 1 wherein the substrate defines a shape selected from the group consisting of a cylinder, a cone, a plane, a sphere, and combinations thereof.

4. The method as recited in claim 1 wherein the first cathode is shaped as a cylinder and the channel is defined by longitudinally extending interior surfaces of the cylinder.

5. The method as recited in claim 4 wherein the longitudinally extending interior surfaces are at least the length of the substrate.

6. The method as recited in claim 1 further comprising a sputter shield disposed between the substrate and the cathode, wherein the shield, the substrate and the cathode move relative to each other.

7. The method as recited in claim 6 wherein the shield, the substrate and the cathode move relative to each other along a longitudinal axis of the cathode.

8. The method as recited in claim 6 wherein shield, the substrate and the cathode move relative to each other along a latitudinal axis of the cathode.

9. The method as recited in claim 6 wherein the shield moves along a longitudinal axis of the cathode.

10. An X-ray diffraction lens having sub 10 nanometer resolutions, the lens comprising a substrate overlaid with discrete regions of metal, the regions integrally molded with the substrate.

11. The lens as recited in claim 10 wherein the substrate is an x-ray transparent material selected from the group consisting of tungsten, sapphire, quartz, silicon, and aluminum oxide.

12. The lens as recited in claim 10 wherein the metal is a high Z material selected from the group consisting of tungsten silicide, molybdenum silicide, silicon, and combinations thereof.

13. The lens as recited in claim 10 wherein radio-opaque regions are flanked by radio-transparent regions.

14. The lens as recited in claim 10 wherein the thickness of the regions are two or more times the width of X-ray collecting regions of the substrate.

15. A method for producing a radiation diffracting material, the method comprising overlaying a conformal film on a radio-opaque round substrate.

16. The method as recited in claim 15 wherein the conformal film comprises radio-opaque regions alternating with radio-transparent regions.

17. The method as recited in claim 15 further comprising applying direct plasma bombardment to predetermined regions of the substrate while the substrate is inserted into a sputtering cathode to form radio-opaque regions on the substrate.

18. The method as recited in claim 17 wherein magnetic fields are deployed axisymmetric to an optical axis of the substrate and directly behind the substrate.
